(19) United States
(12) Patent Application Publication
(10) Pub. No.: US 2012/0228589 A1
(43) Pub. Date: Sep. 13, 2012

(54) LIGHT-EMITTING ELEMENT, LIGHT-EMITTING APPARATUS, DISPLAY APPARATUS, AND ELECTRONIC DEVICE

(75) Inventor: Masayuki MITSUYA, Chino-shi (JP)

(73) Assignee: SEIKO EPSON CORPORATION, Tokyo (JP)

(21) Appl. No.: 13/411,030

(22) Filed: Mar. 2, 2012

(30) Foreign Application Priority Data
Mar. 7, 2011 (JP) 2011-049641

(51) Int. Cl. H01L 51/54

(52) U.S. Cl. 257/40; 257/E51.026

(57) ABSTRACT

A light-emitting element has an anode, a cathode, a first light-emitting layer, a second light-emitting layer, and a carrier-generating layer. The first light-emitting layer is disposed between the anode and the cathode and, when electric current flows between the anode and the cathode, emits light. The second light-emitting layer is disposed between the cathode and the first light-emitting layer and, when electric current flows between the anode and the cathode, emits light. The carrier-generating layer is disposed between the first light-emitting layer and the second light-emitting layer and can generate holes and electrons. The carrier-generating layer has two layers stacked in contact with each other, an n-type electron transport layer and an electron-accepting layer. The n-type electron transport layer can transport electrons and is formed to face the first light-emitting layer, whereas the electron-accepting layer can accept electrons and is formed to face the second light-emitting layer. The n-type electron transport layer and the electron-accepting layer both contain an electron injection material.

### BACKGROUND

1. Technical Field

The present invention relates to a light-emitting element, a light-emitting apparatus, a display apparatus, and an electronic device.

2. Related Art

Organic electroluminescent elements (organic EL elements) are light-emitting elements composed of an anode, a cathode, and at least one organic light-emitting layer inserted between them. Upon the application of an electric field between the anode and the cathode, holes in the anode and electrons in the cathode are injected into the light-emitting layer or layers and recombine with each other in the light-emitting layer or layers, generating excitons. These excitons release energy in the form of light while returning to the ground state.

A known example of such light-emitting elements is those having two or more light-emitting layers between the anode and the cathode and further having charge-generating (carrier-generating) layer or layers inserted between these light-emitting layers (e.g., see JP-A-2007-598448).

In light-emitting elements of this type, an electric field is applied between the anode and the cathode, and holes and electrons are generated in the charge-generating layer or layers and supplied to the light-emitting layers. This means that the holes and electrons supplied by the charge-generating layer or layers, in addition to those supplied by the anode and the cathode, can also contribute to the light emission from the light-emitting layers. Light-emitting elements of this type can thus emit brighter light and are more efficient than those having only one light-emitting layer. Even when used with a low electric current, furthermore, they can still emit brighter light than single-light-emitting-layer ones. As a result, light-emitting elements of this type can work for a long life with little deterioration.

On the other hand, light-emitting elements of known types begin to generate heat and become highly electrically-resistive as they continuously operate with a constant electric current, and in such a state they require a very high voltage to drive.

### SUMMARY

An advantage of some aspects of the invention is that they provide a light-emitting element that can continuously operate with a constant electric current with little increase in voltage requirement and, furthermore, provide a light-emitting apparatus, a display apparatus, and an electronic device using this light-emitting element.

Such aspects of the invention can be achieved as follows.

A light-emitting element according to an aspect of the invention has an anode, a cathode, a first light-emitting layer, a second light-emitting layer, and a carrier-generating layer. The first light-emitting layer is disposed between the anode and the cathode and, when electric current flows between the anode and the cathode, emits light. The second light-emitting layer is disposed between the cathode and the first light-emitting layer and, when electric current flows between the anode and the cathode, emits light. The carrier-generating layer is disposed between the first light-emitting layer and the second light-emitting layer and can generate holes and electrons. The carrier-generating layer has two layers stacked in contact with each other, an n-type electron transport layer and an electron-accepting layer. The n-type electron transport layer can transport electrons and is formed to face the first light-emitting layer, whereas the electron-accepting layer can accept electrons and is formed to face the second light-emitting layer. The n-type electron transport layer and the electron-accepting layer both contain an electron donor.

The light-emitting element according to this aspect of the invention can operate with effectively reduced or prevented increase in voltage requirement due to increase in its electrical resistance even after it begins to generate heat after long use.

Preferably, the n-type electron transport layer contains an electron transport material in addition to the electron donor.

When containing an electron transport material, the n-type electron transport layer has excellent electron transport and electron injection properties and thus can efficiently transport and inject the electrons generated in the carrier-generating layer into the first light-emitting layer.

Preferably, the electron-accepting layer contains an aromatic cyanide in addition to the electron donor.

Aromatic cyanides are good electron acceptors and thus, when contained in the electron-accepting layer, can help the carrier-generating layer generate holes and electrons.

Preferably, this aromatic cyanide is a hexaazatriphenylene derivative.

Hexaazatriphenylene derivatives are excellent electron acceptors and thus, when contained in the electron-accepting layer, can help this layer adequately withdraw electrons from the next layer on the cathode side and efficiently transport the withdrawn electrons toward the anode.

Preferably, the electron donor consists of one or more kinds selected from alkali metals, alkaline-earth metals, alkali metal compounds, and alkaline-earth metal compounds.

These electron donors have excellent electron injection properties and thus can efficiently inject electrons generated in the carrier-generating layer into the first light-emitting layer.

Preferably, the electron donor contained in the n-type electron transport layer and that contained in the electron-accepting layer are of the same kind.

This allows the carrier-generating layer to generate charges with a low voltage, and thereby the light-emitting element can continuously operate with a constant electric current with the generation of heat therefrom reduced and the temperature thereof kept relatively low.

In the electron-accepting layer, preferably, the electron donor content is in a range of 0.5 wt % (percent by weight) to 10 wt %, inclusive.

When having a content ratio in this range, the electron donor in the electron-accepting layer can be effectively prevented from diffusing into the first and second light-emitting layers.

In the n-type electron transport layer, preferably, the electron donor content is in a range of 1.0 wt. % to 5.0 wt %, inclusive.

When the electron donor content is in this range, the n-type electron transport layer can have equally excellent electron transport and electron injection properties, and the electron donor in the n-type electron transport layer can be effectively prevented from diffusing into the first and second light-emitting layers.

Preferably, the electron donor content of the electron-accepting layer is higher than that of the n-type electron transport layer.

This leads to smoother movement of charges (in particular, electrons) within the carrier-generating layer.

Preferably, the light-emitting element further has a third light-emitting layer. This third-emitting layer is disposed between the second light-emitting layer and the cathode and, when electric current flows between the anode and the cathode, emits light.

This ensures that the first, second, and third light-emitting layers can emit equally intense light beams. When these three light-emitting layers emit red, green, and blue lights, for example, the light-emitting element as a whole can emit white light.

A light-emitting apparatus according to another aspect of the invention has a light-emitting element according to the above aspect of the invention.

This light-emitting apparatus can operate with a constant electric current for a long period of time with little increase in voltage requirement.

A display apparatus according to yet another aspect of the invention has a light-emitting apparatus according to the above aspect of the invention.

This display apparatus is stable and highly reliable in operation.

An electronic device according to yet another aspect of the invention has a display apparatus according to the above aspect of the invention.

This electronic device is reliable in displaying information.

### BRIEF DESCRIPTION OF THE DRAWINGS

The invention will be described with reference to the accompanying drawings, wherein like numbers reference like elements.

FIG. 1 schematically illustrates a vertical cross-section of a light-emitting element according to a preferred embodiment of an aspect of the invention.

FIG. 2 is a vertical cross-sectional diagram illustrating a constitution of a display panel as an application of the display apparatus according to an aspect of the invention.

FIG. 3 is a perspective diagram illustrating a constitution of a mobile (or notebook) PC as an application of the electronic device according to an aspect of the invention.

FIG. 4 is a perspective diagram illustrating a constitution of a mobile phone (or any other type of personal communicating device) as an application of the electronic device according to an aspect of the invention.

FIG. 5 is a perspective diagram illustrating a constitution of a digital still camera as an application of the electronic device according to an aspect of the invention.

### DESCRIPTION OF EXEMPLARY EMBODIMENTS

The following describes the light-emitting element, light-emitting apparatus, display apparatus, and electronic device according to aspects of the invention on the basis of preferred embodiments illustrated in the accompanying drawings.

### Light-Emitting Element

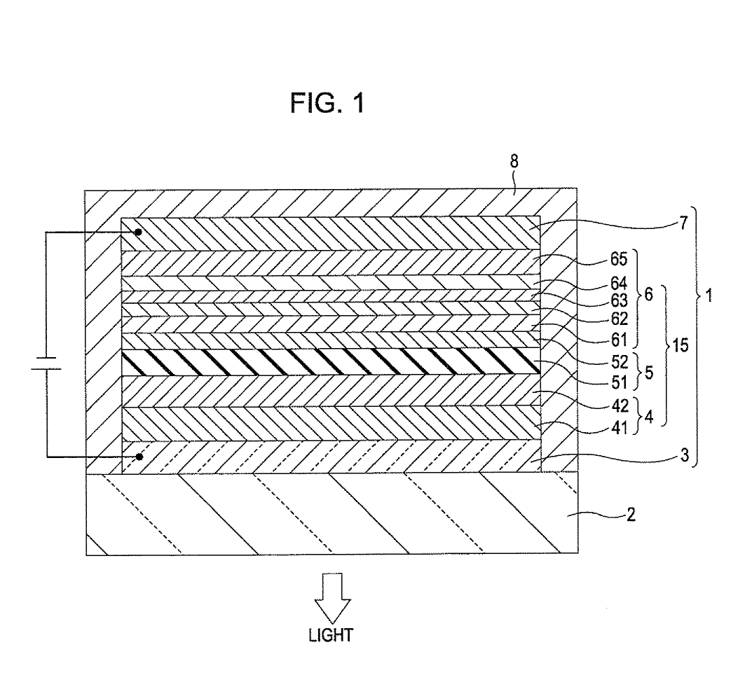

FIG. 1 schematically illustrates a vertical cross-section of a light-emitting element according to a preferred embodiment of an aspect of the invention. For convenience of explanation, the top and bottom in FIG. 1 are hereinafter regarded as the top and bottom of the light-emitting element, respectively.

The light-emitting element (EL element) 1 has an anode 3, a first light-emitting portion (a first light-emitting unit) 4, a carrier-generating layer 5, a second light-emitting portion (a second light-emitting unit) 6, and a cathode 7 stacked in this order.

In other words, the light-emitting element 1 has a laminate 15 inserted between two electrodes (i.e., between the anode 3 and the cathode 7), and this laminate 15 has the first light-emitting portion 4, the carrier-generating layer 5, and the second light-emitting portion 6 stacked in this order.

The first light-emitting portion 4 is a laminate having a hole transport layer 41 and a first light-emitting layer 42 stacked in this order from the anode 3 side to the cathode 7 side. The second light-emitting portion 6 is a laminate having a hole transport layer 61, a second light-emitting layer 62, a third light-emitting layer 63, a hole-blocking layer 64, and an electron transport layer 65 stacked in this order from the anode 3 side to the cathode 7 side.

The light-emitting element 1 as a whole is formed on a substrate 2 and sealed with a sealing member 8.

In this light-emitting element 1, the carrier-generating layer 5 generate carriers (holes and electrons) when driving voltage is applied between the anode 3 and the cathode 7. The first light-emitting layer 42 receives the holes supplied (injected) by the anode 3 and the electrons supplied (injected) by the carrier-generating layer 5. The second light-emitting layer 62 and the third light-emitting layer 63 receive the electrons supplied (injected) by the cathode 7 and the holes supplied (injected) by the carrier-generating layer 5. In each light-emitting layer, the holes and the electrons recombine with each other and release recombination energy, and the released energy generates excitons. These excitons release energy (fluorescence or phosphorescence), or in other words emit light, while returning to the ground state.

The first light-emitting layer 42, the second light-emitting layer 62, and the third light-emitting layer 63 can thereby individually emit light. As a result, this light-emitting element 1 is more efficient and requires lower voltage to drive than those having only one light-emitting layer.

One important reason for the high efficiency of this light-emitting element 1 is that the electrons and holes generated in the carrier-generating layer 5 are distributed to the first light-emitting portion 4 and the second light-emitting portion 6, respectively. This allows the light-emitting element 1 to emit light of enhanced brightness, and thus the light-emitting element 1 is highly efficient.

When these three light-emitting layers 42, 62, and 63 emit red, green, and blue lights, for example, the light-emitting element 1 as a whole can emit white light.

The substrate 2 supports the anode 3. The light-emitting element 1 according to this embodiment emits light through the substrate 2 (the bottom-emission structure), and thus the substrate 2 and the anode 3 are substantially transparent (colorless and transparent, colored and transparent, or translucent).

Examples of materials for the substrate 2 are resin materials such as polyethylene terephthalate, polyethylene naphthalate, polypropylene, cycloolefin polymers, polyamides, polyethersulfone, polymethyl methacrylate, polycarbonates, and polyarylates, glass materials such as quartz glass and soda lime glass, and so forth, and these materials may be used singly or in combination of two or more kinds.

The average thickness of the substrate 2 is not particularly limited; however, it is preferably in a range of 0.1 mm to 30 mm, inclusive, and more preferably 0.1 mm to 10 mm, inclusive.

When the light-emitting element 1 emits light through the surface opposite the substrate 2 (the top-emission structure), the substrate 2 may be a transparent substrate or an opaque substrate.

Examples of appropriate opaque substrates include those made of ceramic materials such as alumina, those made of metals such as stainless steel and coated with an oxide film (an insulating film), and those made of resin materials.

The light-emitting element 1 is formed on this substrate 2. The following details the individual components of the light-emitting element 1.

### Anode

The anode 3 is an electrode that injects holes into the first light-emitting portion 4 described later. Preferably, this anode 3 is made of a highly electroconductive material having a high work function.

Examples of materials for the anode 3 are oxides such as ITO (indium tin oxide), IZO (indium zinc oxide), In₃O₃, SnO₂, Sb-containing SnO₂, and Al-containing ZnO, metals such as Au, Pt, Ag, and Cu, alloys of these metals, and so forth, and these materials may be used singly or in combination of two or more kinds.

The average thickness of the anode 3 is not particularly limited; however, it is preferably in a range of 10 nm to 200 nm, inclusive, and more preferably 50 nm to 150 nm, inclusive.

### First Light-Emitting Portion

As described above, the first light-emitting portion 4 has a hole transport layer 41 and a first light-emitting layer 42.

In this first light-emitting portion 4, the first light-emitting layer 42 receive the holes and electrons supplied (injected) through the hole transport layer 41 and the n-type electron transport layer 51 described later, respectively. In the first light-emitting layer 42, the holes and the electrons recombine with each other and release recombination energy, and the released energy generates excitons. These excitons release energy (fluorescence or phosphorescence) while returning to the ground state; as a result, the first light-emitting layer 42 emits light.

The following details the individual layers of this first light-emitting portion 4.

### Hole Transport Layer

The hole transport layer 41 transports the holes injected by the anode 3 to the first light-emitting layer 42.

The material of this hole transport layer 41 may be a p-type polymer, a p-type low-molecular-weight compound, or any appropriate combination of them, and more specific examples thereof are tetraarylbenzidine derivatives such as N,N′-di(1-naphthyl)-N,N′-diphenyl-1,1′-diphenyl-4,4′-diamine (NPD) and N,N′-diphenyl-N,N′-bis(3-methylphenyl)-1,1′-diphenyl-4,4′-diamine (TPD), tetraaryldiaminofluorenes and their derivatives (amines), and so forth, and these compounds or derivatives may be used singly or in combination of two or more kinds.

Among others, hole transport materials having a benzidine structure are preferable, and tetraarylbenzidine and its derivatives are more preferable. These materials improve the efficiency of both the injection of holes from the anode 3 to the hole transport layer 41 and the subsequent transport of the holes to the first light-emitting layer 42.

The average thickness of the hole transport layer 41 is not particularly limited; however, it is preferably in a range of 10 nm to 150 nm, inclusive, and more preferably 10 nm to 100 nm, inclusive.

First light-emitting layer

The first light-emitting layer 42 contains a light-emitting material.

When the first light-emitting layer 42 receives the holes and electrons supplied (injected) by the anode 3 and the cathode 7, respectively, the light-emitting material works to make the holes and the electrons recombine with each other. The holes and electrons then release recombination energy, the released energy generates excitons, and these excitons release energy (fluorescence or phosphorescence), or in other words emit light, while returning to the ground state.

No particular limitation is imposed on the kind of this light-emitting material; one or a combination of two or more kinds of fluorescent or phosphorescent materials may be used depending on the intended color of the light emitted by the first light-emitting layer 42.

More specifically, examples of appropriate red fluorescent materials include perylene derivatives such as tetraaryldiindenoperylene derivatives, europium complexes, benzopyran derivatives, rhodamine derivatives, benzothioxanthene derivatives, porphyrin derivatives, Nile red, {2-(1,1-dimethylethyl)-6-[2-(2,3,6,7-tetrahydro-1,1,7,7-tetramethyl-1H,5H-benzo[ij]quinolizin-9-yl)ethenyl]-4H-pyran-4H-ylidene}propane dinitrile (DCJTB), and 4-(dicyanomethylene)-2-methyl-6-(p-dimethylaminostyryl)-4H-pyran (DCM).

Examples of appropriate blue fluorescent materials include distyryldiamine derivatives, distyryl derivatives, fluoranthene derivatives, pyrene derivatives, perylene and its derivatives, anthracene derivatives, benzoxazole derivatives, benzothiazole derivatives, benzimidazole derivatives, chrysene derivatives, phenanthrene derivatives, distyrylbenzene derivatives, tetraphenylbutadiene, 4,4′-bis(9-ethyl-3-carbazovinylene)-1,1′-biphenyl(BCzVBi), poly[(9,9-dioctylfluoren-2,7-diyl)-co-(2,5-dimethoxybenzen-1,4-diyl)], poly[(9,9-dihexyloxyfluoren-2,7-diyl)-ortho-co-(2-methoxy-5-[(2-ethoxyhexyloxy]phenylen-1,4-diyl)], poly[(9,9-dioctylfluoren-2,7-diyl)-co-(ethynylbenzene)], and BD102 (a trade name, Idemitsu Kosan Co., Ltd.).

Examples of appropriate green fluorescent materials include coumarin derivatives, quinacridone derivatives, 9,10-bis[(9-ethyl-3-carbazole)-vinylenyl]-anthracene, poly(9,9-dihexyl-2,7-vinylenefluorenylene), poly[(9,9-dioctylfluoren-2,7-diyl)-co-(1,4-diphenylene-vinylene-2-methoxy-5-{2-ethylhexyloxy}benzene)], and poly[(9,9-dioctyl-2,7-divinylenefluorenylene)-ortho-co-(2-methoxy-5-{2-ethoxylhexyloxy}-1,4-phenylene)].

Examples of appropriate yellow fluorescent materials include compounds having a naphthacene skeleton such as rubrene materials, for example, naphthacene derivatives having one or more (preferably, two to six) aryl groups (preferably, phenyl groups) as substituents in one or more positions and monoindenoperylene derivatives.

Examples of appropriate red phosphorescent materials include complexes of iridium, ruthenium, platinum, osmium, rhenium, palladium, and other similar metals with or without one or more ligands thereof having a particular skeleton such as phenylpyridine, bipyridyl, or porphyrin skeleton. More specific examples include tris(1-phenylisoquinoline)iridium (Ir(piq)3), bis[2-(2′-benzo[4,5-α]thienyl)pyridinato-N,C³′]iridium (acetylacetonate) (btp2Ir(acac), chemical formula (1)), 2,3,7,8,12,13,17,18-octaethyl-12H,23H-porphyrin-platinum (II), bis[2-(2′-benzo[4,5-α]thienyl)pyridinato-N,C³′]iridium, and bis(2-phenylpyridine)iridium (acetylacetonate).

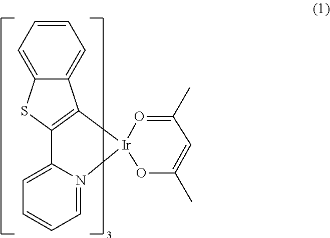

Examples of appropriate blue phosphorescent materials include complexes of iridium, ruthenium, platinum, osmium, rhenium, palladium, and other similar metals. More specific examples include bis[4,6-difluorophenylpyridinato-N,C²′]-picolinate-iridium, tris[2-(2,4-difluorophenyl)pyridinato-N,C²′]iridium, bis[2-(3,5-trifluoromethyl)pyridinato-N,C²′]-picolinate-iridium, and bis(4,6-difluorophenylpyridinato-N,C²′)iridium (acetylacetonate).

Examples of appropriate green phosphorescent materials include complexes of iridium, ruthenium, platinum, osmium, rhenium, palladium, and other similar metals. In particular, complexes of these metals one or more ligands of which have a particular skeleton such as phenylpyridine, bipyridyl, or porphyrin skeleton are preferable. More specific examples include fac-tris(2-phenylpyridine)iridium (Ir(ppy)3, chemical formula (2)), bis(2-phenylpyridinato-N,C²′)iridium (acetylacetonate), and fac-tris[5-fluoro-2-(5-trifluoromethyl-2-pyridine)phenyl-C,N]iridium.

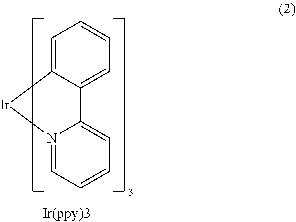

Besides the light-emitting material, the first light-emitting layer 42 may contain a host material for the light-emitting material as the guest material. The first light-emitting layer 42 of this type can be formed by, for example, adding the light-emitting material (guest material) as a dopant to the host material.

This host material makes holes and electrons recombine with each other and generate excitons, and also transfers the energy of the excitons to the light-emitting material (by Forster energy transfer or Dexter energy transfer) to excite the light-emitting material.

No particular limitation is imposed on the kind of the host material. For fluorescent materials, host materials including the following may be used singly or in combination of two or more kinds: rubrene and its derivatives, distyrylarylene derivatives, naphthacene materials such as bis(p-biphenyl)naphthacene, anthracene materials such as 3-tert-butyl-9,10-di(naphth-2-yl)anthracene (TBADN), perylene derivatives such as bis-ortho-biphenylyl perylene, pyrene derivatives such as tetraphenylpyrene, distyrylbenzene derivatives, stilbene derivatives, distyrylamine derivatives, quinolinolato metal complexes such as bis(2-methyl-8-quinolinolato)(p-phenylphenolato)aluminum (BAlq) and tris(8-quinolinolato)aluminum complex (Alq₃), triarylamine derivatives such as triphenylamine tetramer, arylamine derivatives, oxadiazole derivatives, silole derivatives, carbazole derivatives, oligothiophene derivatives, benzopyran derivatives, triazole derivatives, benzoxazole derivatives, benzothiazole derivatives, quinoline derivatives, coronene derivatives, amines, 4,4′-bis(2,2′-diphenylvinyl)biphenyl(DPVBi), and IDE120 (a trade name, Idemitsu Kosan Co., Ltd.). When the light-emitting material emits blue or green light, IDE120 (Idemitsu Kosan Co., Ltd.), anthracene materials, and dianthracene materials are preferable. When the light-emitting material emits red light, rubrene and its derivatives, naphthacene materials, and perylene derivatives are preferable.

For phosphorescent materials, host materials including the following may be used singly or in combination of two or more kinds: carbazole derivatives such as 3-phenyl-4-(1′-naphthyl)-5-phenyl carbazole and 4,4′-N,N′-dicarbazole-biphenyl (CBP, chemical formula (3)), phenanthroline derivatives, triazole derivatives, quinolinolato metal complexes such as tris(8-quinolinolato)aluminum complex (Alq) and bis-(2-methyl-8-quinolinolato)-4-(phenylphenolato)aluminum, carbazolyl compounds such as N-dicarbazolyl-3,5-benzene, poly(9-vinylcarbazole), 4,4′,4″-tris(9-carbazolyl)triphenylamine, and 4,4′-bis(9-carbazolyl)-2,2′-dimethylbiphenyl, and 2,9-dimethyl-4,7-diphenyl-1,10-phenanthroline (BCP).

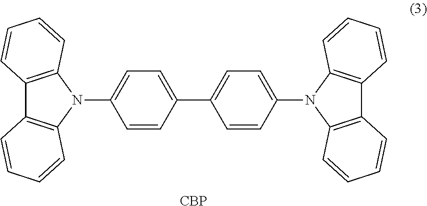

When a host material is used in addition to the light-emitting material (guest material) as above, the light-emitting material content (doping level) of the first light-emitting layer 42 is preferably in a range of 0.1 wt % to 30 wt %, inclusive, and more preferably 0.5 wt % to 20 wt %, inclusive. When the light-emitting material content is in any of these ranges, optimal light-emission efficiency is ensured.

Preferably, the light-emitting material used in the first light-emitting layer 42 is a fluorescent material. In other words, the first light-emitting layer 42 preferably contains a light-emitting material that emits fluorescence when electric current flows between the anode 3 and the cathode 7.

Light-emitting materials that emit phosphorescence (phosphorescent materials) are superior to those that emit fluorescence (fluorescent materials) in terms of light-emission efficiency. However, the light-emitting properties of phosphorescent materials are sensitive to the impurity content; their light-emitting properties vary when light-emitting elements using them are continuously operated and the impurity content is accordingly changed. The use of fluorescent materials, whose light-emitting properties are less sensitive to the impurity content than those of phosphorescent materials, as the light-emitting material of the first light-emitting layer 42 ensures stable light-emitting properties of the first light-emitting layer 42 even after the materials of the n-type electron transport layer 51 described later diffuse into the first light-emitting layer 42 during continuous operation of the light-emitting element 1.

Preferably, the peak emission wavelength of the first light-emitting layer 42 is shorter than that of the second light-emitting layer 62 described later. In other words, the peak emission wavelength of the second light-emitting layer 62 is preferably longer than that of the first light-emitting layer 42. This ensures that the first light-emitting layer 42 and the second light-emitting layer 62 emit equally intense light beams.

The peak emission wavelength of the first light-emitting layer 42 is preferably equal to or shorter than 500 nm, more preferably in a range of 400 nm to 490 nm, inclusive, and even more preferably 430 nm to 480 nm, inclusive. In other words, the first light-emitting layer 42 preferably emits blue light.

The shorter the peak emission wavelength of a light-emitting element is, the more difficult to drive to emit light the light-emitting material is. In the first light-emitting layer 42, with which no other light-emitting layers are in contact, however, the energy for light emission can scarcely escape out to other light-emitting layers. This allows the first light-emitting layer 42 to emit light efficiently even when it contains a light-emitting material having a relatively short peak emission wavelength.

The average thickness of the first light-emitting layer 42 is not particularly limited; however, it is preferably in a range of 30 nm to 100 nm, inclusive, more preferably 30 nm to 70 nm, inclusive, and even more preferably 30 nm to 50 nm, inclusive. This ensures that the light-emitting properties of the first light-emitting layer 42 remain good even after the materials of the n-type electron transport layer 51 of the carrier-generating layer 5 described later, in particular, an electron donor, diffuse into the first light-emitting layer 42. When the first light-emitting layer 42 has such a moderate thickness, furthermore, the initial voltage requirement of the light-emitting element 1 is not so high; the light-emitting element 1 can be driven with a low voltage.

Although in this embodiment the first light-emitting layer 42 is a single light-emitting layer, the first light-emitting layer 42 may be a laminate having two or more light-emitting layers. When the first light-emitting layer 42 is a laminate having two or more light-emitting layers, the light-emitting layers may emit the same or different colors of light, and an intermediate layer or layers may be inserted between the light-emitting layers.

Likewise, although in this embodiment the first light-emitting layer 42 is in contact with the n-type electron transport layer 51 of the carrier-generating layer 5 described later, an additional electron transport layer or layers may exist between these two layers. When an additional electron transport layer or layers are used, this electron transport layer or layers may be those having the same constitution as the electron transport layer 65 described later.

### Carrier-Generating Layer

The carrier-generating layer 5 has generates carriers (holes and electrons).

This carrier-generating layer 5 is a laminate having an n-type electron transport layer 51 and an electron-accepting layer 52 stacked in this order from the anode 3 side to the cathode 7 side.

In other words, the carrier-generating layer 5 has two layers stacked in contact with each other, the n-type electron transport layer 51 and the electron-accepting layer 52, the former formed to face the first light-emitting layer 42 and the latter formed to face the second light-emitting layer 62 described later.

The average thickness of the carrier-generating layer 5 is preferably in a range of 5 nm to 80 nm, inclusive, and more preferably 20 nm to 70 nm, inclusive. This allows the carrier-generating layer 5 to adequately fulfill its function (generation of carriers) with little increase in the voltage requirement of the light-emitting element 1.

The following details the individual layers of the carrier-generating layer 5.

n-Type Electron Transport Layer

The n-type electron transport layer 51 is disposed between the first light-emitting layer 42 and the electron-accepting layer 52 described below and transports electrons from the electron-accepting layer 52 to the first light-emitting layer 42.

In this aspect of the invention, the n-type electron transport layer 51 is mainly composed of an electron transport material, which is a material capable of transporting electrons, and further contains an electron donor, which is a material capable of injecting electrons into other materials.

This n-type electron transport layer 51, which contains both an electron transport material and an electron donor, have quite excellent electron transport and electron injection properties. Even when the light-emitting element 1 operates with a low voltage, thus, the electrons accepted by the electron accepting layer 52 can be efficiently injected into the n-type electron transport layer 51 and then, via this n-type electron transport layer 51, efficiently transported toward the anode 3. As a result, the light-emitting element 1 can operate with the generation of heat therefrom reduced and the temperature thereof kept relatively low.

Furthermore, in the n-type electron transport layer 51, which is composed of an electron transport material doped with an electron donor, the molecules of the electron transport material receive electrons from those of the electron donor and turn into radical anions. As a result, the carrier-generating layer 5 can generate an increased number of carriers.

Examples of electron transport materials for the n-type electron transport layer 51 are quinoline derivatives such as organometallic complexes whose ligands are molecules of 8-quinolinol or its derivative, for example, tris(8-quinolinolato)aluminum complex (Alq₃), oxadiazole derivatives such as 1,3-bis(N,N-t-butyl-phenyl)-1,3,4-oxadiazole (OXD-7), perylene derivatives, pyridine derivatives, pyrimidine derivatives, quinoxaline derivatives, diphenylquinone derivatives, nitro-substituted fluorene derivatives, and so forth, and these electron transport materials may be used singly or in combination of two or more kinds.

Examples of electron donors for the n-type electron transport layer 51 include various kinds of inorganic insulating and inorganic semiconducting materials.

Examples of appropriate inorganic insulating materials are alkali metal chalcogenides (oxides, sulfides, selenides, and tellurides), alkaline-earth metal chalcogenides, alkali metal halides, alkaline-earth metal halides, and so forth, and these inorganic insulating materials may be used singly or in combination of two or more kinds. These inorganic insulating materials have excellent electron injection properties and thus can efficiently inject the electrons generated in the carrier-generating layer 5 into the first light-emitting layer 42. As a result, electrons can be injected with a low voltage, and the light-emitting element 1 can continuously operate with a constant electric current with the generation of heat therefrom reduced and the temperature thereof kept relatively low.

Examples of appropriate alkali metal chalcogenides include Li₂O, LiO, Na₂S, Na₂Se, and NaO.

Examples of appropriate alkaline-earth metal chalcogenides include CaO, BaO, SrO, BeO, BaS, MgO, and CaSe.

Examples of alkali metal halides include CsF, LiF, NaF, KF, LiCl, KCl, and NaCl.

Examples of alkaline-earth metal halides include CaF₂, BaF₂, SrF₂, MgF₂, and BeF₂.

As for inorganic semiconducting materials, examples of appropriate ones are oxides, nitrides, oxynitrides, and other similar compounds containing at least one of the following elements: Li, Na, Ba, Ca, Sr, Yb, Al, Ga, In, Cd, Mg, Si, Ta, Sb, and Zn. These inorganic semiconducting materials may be used singly or in combination of two or more kinds.

The electron donor for the n-type electron transport layer 51 is preferably one or a combination of two or more kinds of alkali metal compounds and alkaline-earth metal compounds, and more preferably Li₂O. This imparts not only excellent electron transport properties but also improved electron injection properties to the n-type electron transport layer 51. Furthermore, alkali metal compounds (e.g., alkali metal chalcogenides and alkali metal halides) have a very low work function, and the light-emitting element 1 can achieve high brightness when the re-type electron transport layer 51 contains one or a combination of them. In particular, Li₂O, which can be easily made to inject electrons with a low voltage, allows the light-emitting element 1 to continuously operate with a constant electric current with the generation of heat therefrom reduced and the temperature thereof kept even lower.

Configured as above, this n-type electron transport layer 51 can also block holes.

Incidentally, this n-type electron transport layer 51, which contains an electron transport material and an electron donor, can be formed by, for example, doping the electron transport material with the electron donor by codeposition or any other appropriate technique with the electron transport material as the host material and the electron donor as the guest material.

The electron donor content (doping level) of the re-type electron transport layer 51 is preferably in a range of 1.0 wt % to 5.0 wt %, inclusive, and more preferably 1.5 wt % to 30 wt %, inclusive. When the electron donor content is in any of these ranges, the n-type electron transport layer 51 can have equally excellent electron transport and electron injection properties, and the electron donor can be effectively prevented from diffusing into the first light-emitting layer 41 and the second light-emitting layer 62.

In addition, the concentration of the electron donor in the n-type electron transport layer 51 may gradually decrease from the cathode 7 side to the anode 3 side; this ensures that the electrons generated in the carrier-generating layer 5 are efficiently transported and injected into the first light-emitting layer 42 and that the electron donor in the n-type electron transport layer 51 is prevented from diffusing into the first light-emitting layer 41, and thereby lengthens the life of the light-emitting element 1. In this case, the change in the concentration of the electron donor may be stepwise or continuous.

The average thickness of the n-type electron transport layer 51 is not particularly limited; however, it is preferably in a range of 10 nm to 100 nm, inclusive, and more preferably in a range of 10 nm to 50 nm. This ensures that the electrons accepted by the electron-accepting layer 52 described below are efficiently transported toward the anode 3 and that the holes coming through the first light-emitting portion 4 are blocked.

### Electron-Accepting Layer

The electron-accepting (-withdrawing) layer 52 is disposed between the first light-emitting layer 42 and the second light-emitting layer 62 and accepts (withdraws) electrons from the next layer on the cathode 7 side (in this embodiment, the hole transport layer 61 of the second light-emitting portion 6 described later). The electrons accepted by the electron-accepting layer 52 are injected into the next layer on the anode 3 side (the n-type electron transport layer 51).

In this aspect of the invention, this electron-accepting layer 52 is mainly composed of an electron-accepting organic compound (an electron acceptor) and further contains an electron donor, which is a material capable of injecting electrons into other materials.

Examples of preferred electron-accepting organic compounds for the electron-accepting layer 52 include aromatic cyanides.

Aromatic cyanides are good electron acceptors and thus, when contained in the electron-accepting layer 52, can help the carrier-generating layer 5 generate holes and electrons.

The electron-accepting layer 52, when mainly composed of an aromatic cyanide, can withdraw electrons from the hole transporting material of its next layer (the hole transport layer 61 described later) upon being in contact with the hole transport layer 61. Thus, upon the contact of the electron-accepting layer 52 with the hole transport layer 61, electrons are generated on the electron-accepting layer 52 side and holes are generated on the hole transport layer 61 side near the interface between the electron-accepting layer 52 and the hole transport layer 61 even with no voltage applied. In this state, application of driving voltage between the anode 3 and the cathode 7 causes the holes generated near the interface between the electron-accepting layer 52 and the hole transport layer 61 to be transported toward the cathode 7 by the driving voltage, and the transported holes contribute to the light emission from the second light-emitting portion 6 described later (more specifically, the second light-emitting layer 62 and the third light-emitting layer 63). On the other hand, the electrons generated near the interface between the electron-accepting layer 52 and the hole transport layer 62 are transported toward the anode 3 by the driving voltage, and contribute to the light emission from the first light-emitting portion 4 (more specifically, the first light-emitting layer 42). The electron-accepting layer 52 can continuously generate holes and electrons in this way as long as the application of driving voltage is continued, and the holes and electrons contribute to light emission from the first light-emitting layer 42, the second light-emitting layer 62, and the third light-emitting layer 63.

Furthermore, aromatic cyanides are relatively stable compounds and are suitable for the formation of the electron-accepting layer 52 by gas-phase film formation such as vapor deposition. Thus, they can be suitably used to prepare the light-emitting element 1, and therewith the light-emitting element 1 can be prepared with consistent quality and in a high yield. Moreover, aromatic cyanides allow the electron-accepting layer 52 to generate charges with a low voltage and thereby ensure that the light-emitting element 1 can continuously operate with a constant electric current with the generation of heat therefrom reduced and the temperature thereof kept relatively low.

No particular limitation is imposed on the kind of the aromatic cyanide as long as it has the above functions; however, it is preferably a hexaazatriphenylene derivative having a cyano group or groups, for example, and more preferably a hexaazatriphenylene derivative represented by formula (4) below.

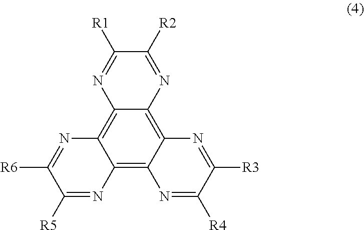

In formula (4), substituents R1 to R6 are independently a cyano group (—CN), a sulfone group (—SO₂R′) a sulfoxide group (—SOR′), a sulfonamide group (—SO₂NR′₂), a sulfonate group (—SO₃R′), a nitro group (—NO₂), or a trifluoromethyl group (—CF₃), and at least one of the substituents R1 to R6 is a cyano group. The symbol R′ represents an alkyl, aryl, or heterocyclic group having 1 to 60 carbon atoms, unsubstituted or substituted with an amine, amide, ether, or ester group or groups.

Such compounds as these are excellent electron acceptors, and thus, when contained in the electron-accepting layer 52, can help this layer adequately withdraw electrons from the next layer (the hole transport layer 61 described later) and efficiently transport the withdrawn electrons toward the anode 3.

Among others, the compound of formula (4) that has all R1 to R6 substituted with cyano groups is particularly preferably used as the aromatic cyanide. More specifically, the aromatic cyanide is particularly preferably hexacyanohexaazatriphenylene, represented by formula (5) below. Such compounds as this have several highly electron-accepting groups, namely cyano groups, and thus, when contained in the electron-accepting layer 52, can help this layer more efficiently withdraw electrons from the components of the next layer (e.g., the hole transport material of the hole transport layer 61 described later). As a result, the carrier-generating layer 5 can generate an increased number of carriers (electrons and holes).

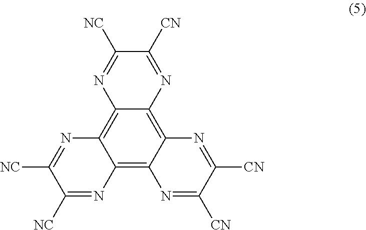

Preferably, the aromatic cyanide exists in an amorphous state in the electron-accepting layer 52. This enhances the effects of aromatic cyanides such as those mentioned above.

Examples of electron donors for the electron-accepting layer 52 include various kinds of inorganic insulating and semiconducting materials; those listed above for the n-type electron transport layer 51 may be used.

The electron donor content (doping level) of the electron-accepting layer 52 is preferably in a range of 0.5 wt % to 10 wt %, inclusive, and more preferably 2.0 wt %, to 7.0 wt %, inclusive. When having a content ratio in any of these ranges, the electron donor in the electron-accepting layer 52 can be effectively prevented from diffusing into the first light-emitting layer 41 and the second light-emitting layer 62.

The average thickness of the electron-accepting layer 52 is preferably in a range of 5 nm to 40 nm, inclusive, and more preferably 10 nm to 30 nm, inclusive. This ensures that the voltage requirement of the light-emitting element 1 is not so high and allows the electron-accepting layer 52 to fulfill its full function (electron-accepting properties).

In this aspect of the invention, this carrier-generating layer 5 contains an electron donor both in the n-type electron transport layer 51 and in the electron-accepting layer 52 as described above. After research, the inventors found that when the carrier-generating layer 5 contained an electron donor both in the n-type electron transport layer 51 and in the electron-accepting layer 52, or in other words when both the n-type electron transport layer 51 and the electron-accepting layer 52 had an electron donor diffusing therein, the light-emitting element 1 could operate with the increase in voltage requirement due to increase in its electrical resistance effectively reduced or prevented even after the light-emitting element 1 began to generate heat after long use, and thereby completed the invention.

In this embodiment, incidentally, the n-type electron transport layer 51 is in contact with the first light-emitting layer 42, and this ensures that the diffusion of the electron donor existing in the n-type electron transport layer 51 into the first light-emitting layer 42 is reduced or prevented; as a result, the effect of the n-type electron transport layer 51 is enhanced.

The electron donor contained in the n-type electron transport layer 51 and that contained in the electron-accepting layer 52 may be different from each other; however, they are preferably of the same family, and more preferably of the same kind. This allows the carrier-generating layer 5 to generate charges with a low voltage, and thereby the light-emitting element 1 can continuously operate with a constant electric current with the generation of heat therefrom reduced and the temperature thereof kept relatively low.

Preferably, the electron donor content of the electron-accepting layer 52 is higher than that of the re-type electron transport layer 51. When this relation is satisfied, the movement of charges (in particular, electrons) within the carrier-generating layer 5 is smoothened. Furthermore, the electron donor diffusion from the n-type electron transport layer 51 into the first light-emitting layer 42 is presumably reduced.

### Second Light-Emitting Portion

As described above, the second light-emitting portion 6 has a hole transport layer 61, a second light-emitting layer 62, a third light-emitting layer 63, a hole-blocking layer 64 (an intermediate layer), and an electron transport layer 65.

In this second light-emitting portion 6, the second light-emitting layer 62 and the third light-emitting layer 63 receive the holes and electrons supplied (injected) through the hole transport layer 61 and the hole-blocking layer 64, respectively. In the second light-emitting layer 62 and the third light-emitting layer 63, the holes and the electrons recombine with each other and release recombination energy, and the released energy generates excitons. These excitons release energy (fluorescence or phosphorescence) while returning to the ground state; as a result, the second light-emitting layer 62 and the third light-emitting layer 63 emit light.

The following details the individual layers of this second light-emitting portion 6.

### Hole Transport Layer

The hole transport layer 61 transports the holes injected by the carrier-generating layer 5 (or more specifically the electron-accepting layer 52) to the second light-emitting layer 62. In addition to this, the hole transport layer 61 blocks the electrons coming through the second light-emitting layer 62 to prevent the deterioration of the carrier-generating layer 5 caused by the electrons reaching the carrier-generating layer 5.

An important point here is that the hole transport layer 61 is disposed between the second light-emitting layer 62 and the carrier-generating layer 5 and is in contact with the carrier-generating layer 5.

This allows the electron-accepting layer 52 to efficiently accept electrons from the hole transport layer 61 as described above. As a result, the carrier-generating layer 5 can generate an increased number of holes and electrons.

Examples of materials for this hole transport layer 61 are the same as those listed above for the hole transport layer 41.

Compared with the other listed compounds, amines are preferred hole transport materials for the hole transport layer 61, and N,N′-di(1-naphthyl)-N,N′-diphenyl-1,1′-diphenyl-4,4′-diamine (NPD) is more preferred one. Such compounds as these, when coming in contact with the carrier-generating layer 5 (or more specifically the electron-accepting layer 52) rapidly withdraw electrons, and holes are rapidly generated and injected.

The average thickness of the hole transport layer 61 is not particularly limited; however, it is preferably in a range of 10 nm to 150 nm, inclusive, and more preferably 10 nm to 100 nm, inclusive. This ensures that holes are efficiently transported to the second light-emitting layer 62 and that the electrons coming through the second light-emitting layer 62 are effectively blocked.

### Second Light-Emitting Layer

The second light-emitting layer 62 contains a light-emitting material.

The kind of this light-emitting material is not particularly limited; such light-emitting materials as those listed above for the first light-emitting layer 42 may be used. The light-emitting material for the second light-emitting layer 62 may be of the same kind as or different from that for the first light-emitting layer 42. Similarly, the color of the light emitted by the second light-emitting layer 62 may be the same as or different from that emitted by the first light-emitting layer 42.

Besides the light-emitting material, the second light-emitting layer 62 may contain a host material for the light-emitting material as the guest material.

When such a combination of a light-emitting material (the guest material) and a host material is used, the light-emitting material content (doping level) of the second light-emitting layer 62 is preferably in a range of 0.1 wt % to 10 wt %, inclusive, and more preferably 0.5 wt % to 5 wt %, inclusive. When the light-emitting material content is in any of these ranges, optimal light-emission efficiency is ensured.

Preferably, the light-emitting material for the second light-emitting layer 62 is a phosphorescent material. In other words, the second light-emitting layer 62 preferably contains a light-emitting material that emits phosphorescent when electric current flows between the anode 3 and the cathode 7.

The use of a phosphorescent material as the light-emitting material for the second light-emitting layer 62 eliminates or reduces the diffusion of the dopant in this layer caused by continuous operation of the light-emitting element 1 and thereby allows the second light-emitting layer 62 to emit light efficiently; as a result, the efficiency of the light-emitting element 1 is improved.

Preferably, the peak emission wavelength of the second light-emitting layer 62 is longer than that of the first light-emitting layer 42. This ensures that the first light-emitting layer 42 and the second light-emitting layer 62 emit equally intense light beams.

The average thickness of the second light-emitting layer 62 is not particularly limited; however, it is preferably in a range of 5 nm to 50 nm, inclusive, more preferably 5 nm to 40 nm, inclusive, and even more preferably 5 nm to 30 nm, inclusive. This reduces the voltage requirement of the light-emitting element 1 and allows the second light-emitting layer 62 to emit light efficiently. Particularly in such a case as this embodiment where the second light-emitting layer 62 and the third light-emitting layer 63 are stacked, a relatively small thickness of the second light-emitting layer 62 permits both the second light-emitting layer 62 and the third light-emitting layer 63 to exist in the recombination area, or more specifically the area in which holes and electrons recombine with each other, and thereby enables these two light-emitting layers to emit equally intense light beams.

### Third Light-Emitting Layer

The third light-emitting layer 63 contains a light-emitting material.

In this embodiment, the third light-emitting layer 63 is in contact with the second light-emitting layer 62. This permits both the second light-emitting layer 62 and the third light-emitting layer 63 to exist in the hole-electron recombination area in the second light-emitting portion 6 with no difficulty. As a result, both the second light-emitting layer 62 and the third light-emitting layer 63 can be easily driven to emit light.

The kind of the light-emitting material for this layer is not particularly limited; such light-emitting materials as those listed above for the first light-emitting layer 42 may be used. The light-emitting material for the third light-emitting layer 63 may be of the same kind as or different from that for the first light-emitting layer 42. Also, the light-emitting material for the third light-emitting layer 63 may be of the same kind as or different from that for the second light-emitting layer 62. Similarly, the color of the light emitted by the third light-emitting layer 63 may be the same as or different from that emitted by the first light-emitting layer 42. And the color of the light emitted by the third light-emitting layer 63 may be the same as or different from that emitted by the second light-emitting layer 62.

Besides the light-emitting material, the third light-emitting layer 63 may contain a host material for the light-emitting material as the guest material.

When such a combination of a light-emitting material (the guest material) and a host material is used, the light-emitting material content (doping level) of the third light-emitting layer 63 is preferably in a range of 0.1 wt % to 30 wt %, inclusive, and more preferably 0.5 wt % to 20 wt %, inclusive. When the light-emitting material content is in any of these ranges, optimal light-emission efficiency is ensured.

Preferably, the light-emitting material for the third light-emitting layer 63 is a phosphorescent material. In other words, the third light-emitting layer 63 preferably contains a light-emitting material that emits phosphorescence when electric current flows between the anode 3 and the cathode 7.

The use of a phosphorescent material as the light-emitting material for the third light-emitting layer 63 eliminates or reduces the diffusion of the dopant in this layer caused by continuous operation of the light-emitting element 1 and thereby allows the third light-emitting layer 63 to emit light efficiently; as a result, the efficiency of the light-emitting element 1 is improved.

Preferably, the peak emission wavelength of the third light-emitting layer 63 is longer than that of the first light-emitting layer 42. This ensures that the first light-emitting layer 42, the second light-emitting layer 62, and the third light-emitting layer 63 emit equally intense light beams.

More preferably, the peak emission wavelength of the third light-emitting layer 63 is shorter than that of the second light-emitting layer 62. This ensures that the first light-emitting layer 42, the second light-emitting layer 62, and the third light-emitting layer 63 emit equally intense light beams.

When the first light-emitting layer 42 emits blue light, therefore, the second light-emitting layer 62 and the third light-emitting layer 63 preferably emit red light and green light, respectively.

The average thickness of the third light-emitting layer 63 is not particularly limited; however, it is preferably in a range of 5 nm to 50 nm, inclusive, more preferably 5 nm to 40 nm, inclusive, and even more preferably 5 nm to 30 nm, inclusive. This reduces the voltage requirement of the light-emitting element 1 and allows the third light-emitting layer 63 to emit light efficiently. Particularly in such a case as this embodiment where the second light-emitting layer 62 and the third light-emitting layer 63 are stacked, a relatively small thickness of the third light-emitting layer 63 permits both the second light-emitting layer 62 and the third light-emitting layer 63 to exist in the recombination area, or more specifically the area in which holes and electrons recombine with each other, and thereby enables these two light-emitting layers to emit equally intense light beams.

Although this embodiment illustrates a constitution in which the second light-emitting portion 6 has two light-emitting layers (i.e., the second light-emitting layer 62 and the third light-emitting layer 63), the second light-emitting portion 6 may have only one light-emitting layer. In other words, either the second light-emitting layer 62 or the third light-emitting layer 63 may be omitted from the second light-emitting portion 6. On the other hand, the second light-emitting portion 6 may have three or more light-emitting layers. In other words, the second light-emitting layer 6 may have one or more additional light-emitting layers besides the second light-emitting layer 62 and the third light-emitting layer 63. When the second light-emitting portion 6 has two or more light-emitting layers, these light-emitting layers may emit the same or different colors of light. When the second light-emitting portion 6 has two or more light-emitting layers, furthermore, an intermediate layer or layers may be inserted between the light-emitting layers.

### Hole-Blocking Layer

The hole-blocking layer 64 blocks holes and thereby prevents the transportation of holes from the third light-emitting layer 63 to the electron transport layer 65 described later. As a result, the deterioration of the electron transport layer 65 caused by holes is prevented. In addition to this, the hole-blocking layer 64 has electron transport properties and thus can transport the electrons received from the electron transport layer 65 to the third light-emitting layer 63.

Examples of materials for this hole-blocking layer 64 are carbazole derivatives such as 3-phenyl-4-(1′-naphthyl)-5-phenyl carbazole and 4,4′-N,N′-dicarbazole-biphenyl (CBP), phenanthroline derivatives, triazole derivatives, quinolinolato metal complexes such as tris(8-quinolinolato)aluminum complex (Alq) and bis-(2-methyl-8-quinolinolato)-4-(phenylphenolato)aluminum, carbazolyl compounds such as N-dicarbazolyl-3,5-benzene, poly(9-vinylcarbazole), 4,4′,4″-tris(9-carbazolyl)triphenylamine, and 4,4′-bis(9-carbazolyl)-2,2′-dimethylbiphenyl, 2,9-dimethyl-4,7-diphenyl-1,10-phenanthroline (BCP), and so forth, and these materials may be used singly or in combination of two or more kinds.

The average thickness of the hole-blocking layer 64 is not particularly limited; however, it is preferably in a range of 1 nm to 50 nm, inclusive, more preferably 3 nm to 30 nm, inclusive, and even more preferably 5 nm to 20 nm, inclusive.

This hole-blocking layer 64 may be omitted depending on the constitution of the second light-emitting layer 62, the third light-emitting layer 63, and the electron transport layer 65 described below.

### Electron Transport Layer

The electron transport layer 65 transports the electrons injected by the cathode 7 to the hole-blocking layer 64, and to the second light-emitting layer 62.

Examples of materials for the electron transport layer 65 (electron transport materials) are quinoline derivatives such as organometallic complexes whose ligands are molecules of 8-quinolinol or its derivative, for example, tris(8-quinolinolato)aluminum complex (Alq₃), oxadiazole derivatives, perylene derivatives, pyridine derivatives, pyrimidine derivatives, quinoxaline derivatives, diphenylquinone derivatives, nitro-substituted fluorene derivatives, and so forth, and these electron transport materials may be used singly or in combination of two or more kinds.

The average thickness of the electron transport layer 65 is not particularly limited; however, it is preferably in a range of 10 nm to 100 nm, inclusive, and more preferably in a range of 10 nm to 50 nm.

### Cathode

The cathode 7 is an electrode that injects electrons into the second light-emitting portion 6. Preferably, this cathode 7 is made of a material having a low work function.

Examples of materials for the cathode 7 are Li, Mg, Ca, Sr, La, Ce, Er, Eu, Sc, Y, Yb, Ag, Cu, Al, Cs, and Rb, alloys of these metals, and so forth, and these metals or alloys may be used singly or in combination of two or more kinds (e.g., as the materials of layers of a laminate).

In particular, when the cathode 7 is made of an alloy, examples of preferred alloys include those of stable metals such as Ag, Al, and Cu, or more specifically MgAg, AlLi, CuLi, and so forth. When used as the material for the cathode 7, these alloys can improve the electron injection efficiency and stability of the cathode 7.

The average thickness of the cathode 7 is not particularly limited; however, it is preferably in a range of 100 nm to 400 nm, inclusive, and more preferably 100 nm to 200 nm, inclusive.

In this embodiment, the light-emitting element 1 has the bottom-emission structure, and thus the cathode 7 does not have to be transparent to light.

### Electron Injection Layer

An electron injection layer may be inserted between the electron transport layer 65 and the cathode 7.

The electron injection layer improves the efficiency of the electron injection from the cathode 7 to the electron transport layer 65.

Examples of materials for this electron injection layer (electron donors) include various kinds of inorganic insulating and inorganic semiconducting materials.

Examples of appropriate inorganic insulating materials are alkali metal chalcogenides (oxides, sulfides, selenides, and tellurides), alkaline-earth metal chalcogenides, alkali metal halides, alkaline-earth metal halides, and so forth, and these inorganic insulating materials may be used singly or in combination of two or more kinds. These inorganic insulating materials, when one or a combination thereof is used as the main ingredient of the electron injection layer, can provide improved electron injection properties. In particular, alkali metal compounds (e.g., alkali metal chalcogenides and alkali metal halides) have a very low work function, and the light-emitting element 1 can achieve high brightness when the electron injection layer contains one or a combination of them.

Examples of appropriate alkali metal chalcogenides include Li₂O, LiO, Na₂S, Na₂Se, and NaO.

Examples of appropriate alkaline-earth metal chalcogenides include CaO, BaG, SrO, BeO, BaS, MgO, and CaSe.

Examples of alkali metal halides include CsF, LiF, NaF, KF, LiCl, KCl, and NaCl.

Examples of alkaline-earth metal halides include CaF₂, BaF₂, SrF₂, MgF₂, and BeF₂.

As for inorganic semiconducting materials, examples of appropriate ones are oxides, nitrides, oxynitrides, and other similar compounds containing at least one of the following elements: Li, Na, Ba, Ca, Sr, Yb, Al, Ga, In, Cd, Mg, Si, Ta, Sb, and Zn. These inorganic semiconducting materials may be used singly or in combination of two or more kinds.

The average thickness of this electron injection layer is not particularly limited; however, it is preferably in a range of 0.1 nm to 1000 nm, inclusive, more preferably 0.2 nm to 100 nm, inclusive, and even more preferably 0.2 nm to 50 nm, inclusive.

### Sealing Member

The sealing member 8 is formed to cover the anode 3, the laminate 15, and the cathode 7 and air-tightly seals them to shut out oxygen and water. This sealing member 8 has several effects such as improved reliability and the prevention of alteration and deterioration (improved durability) of the light-emitting element 1.

Examples of materials for the sealing member 8 include metals such as Al, Au, Cr, Nb, Ta, and Ti, alloys of these metals, silicon oxides, and various kinds of resin materials. When the sealing member 8 is made of any kind of electroconductive material, the gap between the sealing member 8 and the anode 3, the laminate 15, and the anode 7 is preferably filled with an insulating film as needed for the prevention of short circuits.

The sealing member 8 may be a plate facing the substrate 2, provided that the space between them is sealed with a sealing material such as a thermosetting resin.

Configured as above, the light-emitting element 1 emits light as follows: voltage is applied between the anode 3 and the cathode 7, and the carrier-generating layer 5 generates holes and electrons; the generated electrons are transported to the first light-emitting layer 42, recombine with the holes injected by the anode 3, and thereby contribute to light emission; and the generated holes are transported to the second light-emitting layer 62 and the third light-emitting layer 63, recombine with the electrons injected by the cathode 7, and thereby contribute to light emission.

Since the first light-emitting layer 41, the second light-emitting layer 62, and the third light-emitting layer 63 can individually emit light in this way, this light-emitting element 1 offers improved efficiency and reduced voltage requirement when compared with those having only one light-emitting layer.

Importantly, in this light-emitting element 1, both the n-type electron transport layer 51 and the electron-accepting layer 52 of the carrier-generating layer 5 contain an electron donor; this ensures that the light-emitting element 1 can operate with the increase in voltage requirement due to increase in its electrical resistance effectively reduced or prevented even after the light-emitting element 1 begins to generate heat after long use.

### Method for Preparing the Light-Emitting Element

A light-emitting element 1 configured as above can be prepared by various methods including the following one.

I. First, a substrate 2 is prepared, and an anode 3 is formed over this substrate 2.

The anode 3 can be formed by various processes including chemical vapor deposition (CVD) processes such as plasma CVD and thermal CVD, dry plating processes such as vacuum deposition, wet plating processes such as electrolytic plating, thermal spraying processes, sol-gel processes, metal-organic deposition (MOD) processes, and metal foil cladding.

II. Then, a first light-emitting portion 4 is formed over the anode 3.

The first light-emitting portion 4 can be formed by sequentially forming a hole transport layer 41 and a first light-emitting layer 42 over the anode 3.

These layers can be formed by CVD processes, dry plating processes such as vacuum deposition and sputtering, and other gas-phase processes.

Instead of such processes, these layers can be formed by dissolving the materials of the layers in a solvent or dispersing them in a dispersion medium, applying the obtained liquid material to the anode 3 (or the layer on it), and then drying the applied liquid material (removing the solvent or dispersion medium).

Examples of appropriate methods for applying the liquid material include various kinds of application methods such as spin coating, roll coating, and ink jet printing. By these application methods, the layers of the first light-emitting portion 4 can be formed relatively easily.

Examples of appropriate solvents and dispersing media for preparing the liquid material include various kinds of inorganic and organic solvents and mixtures of them.

In addition, the drying operation can be performed by various processes including leaving the applied liquid material at atmospheric pressure or a reduced pressure, heating, and spraying with an inert gas.

The anode 3 may be treated on its top surface with oxygen plasma prior to this step. This has several effects including imparting lyophilicity to the top surface of the anode 3, removing adhesive organic matter from the top surface of the anode 3 (cleaning the anode 3), and adjusting the work function of the superficial portion of the anode 3.

An example of preferred conditions of the oxygen plasma treatment is as follows: plasma power: approximately 100 to 800 W; oxygen flow rate: approximately 50 to 100 mL/min; transport speed of the material under treatment (the anode 3): approximately 0.5 to 10 mm/sec; temperature of the substrate 2: approximately 70 to 90° C.

III. Then, a carrier-generating layer 5 is formed over the first light-emitting portion 4.

The carrier-generating layer 5 can be formed by sequentially forming an n-type electron transport layer 51 and an electron-accepting layer 52 over the first light-emitting portion 4.

The layers constituting the carrier-generating layer 5 can be formed by CVD processes, dry plating processes such as vacuum deposition and sputtering, and other gas-phase processes.

Instead of such processes, these layers can be formed by dissolving the materials of the layers constituting the carrier-generating layer 5 in a solvent or dispersing them in a dispersion medium, applying the obtained liquid material to the first light-emitting portion 4, and then drying the applied liquid material (removing the solvent or dispersion medium).

IV. Then, a second light-emitting portion 6 is formed over the carrier-generating layer 5.

The second light-emitting portion 6 can be formed in the same way as the first light-emitting portion 4.

V. Then, a cathode 7 is formed over the second light-emitting portion G.

The cathode 7 can be formed by various processes including vacuum deposition, sputtering, metal foil cladding, and application and firing of ink based on metal fine particles.

By these operations, the light-emitting element is obtained.

Finally, a sealing member 8 is put on the obtained light-emitting element 1 to cover it, and then bonded to the substrate 2.

This light-emitting element 1 can be used as, for example, a light source. Furthermore, a matrix of several light-emitting elements 1 constituted as above can serve as a component of a display panel (an embodiment of the display apparatus according to an aspect of the invention).

The drive system of the display apparatus is not particularly limited; it may be the active matrix system or the passive matrix system.

### Display Apparatus

The following describes a display panel as an embodiment of the display apparatus according to an aspect of the invention.

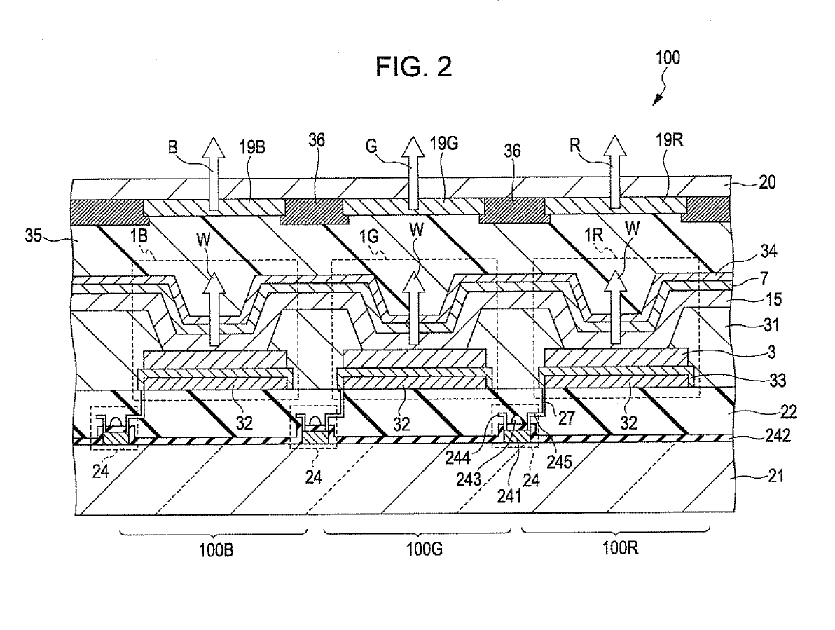

FIG. 2 is a vertical cross-sectional diagram illustrating a constitution of a display panel as an application of the display apparatus according to an aspect of the invention.

The display panel 100 illustrated in FIG. 2 has a substrate 21, sub-pixels 100R,100G, and 100E having light-emitting elements 1R, 1G, and 1B and color filters 19R, 19G, and 19B formed correspondingly thereto, and driving transistors 24 for driving the light-emitting elements 1R, 1G, and 1B. This display panel 100 has the top-emission structure.

The substrate 21 has the driving transistors 24 formed thereon, and these driving transistors 24 are covered with a planarizing layer 22 made of an insulating material.

Each driving transistor 24 has a semiconductor layer 241 made of silicon, a gate insulating layer 242 formed on the semiconductor layer 241, and a gate electrode 243, a source electrode 244, and a drain electrode 245 formed on the gate insulating layer 242.

The planarizing layer 22 has the light-emitting elements 1R, 1G, and 1B formed thereon correspondingly to the driving transistors 24.

The light-emitting elements 1R each have a reflection film 32, a corrosion protection film 33, an anode 3, a laminate (an organic EL light-emitting portion) 15, a cathode 7, and a cathode coating 34 stacked in this order on the planarizing layer 22. In this embodiment, the anode 3 is formed for each of the light-emitting elements 1R, 1G, and 1B to serve as a pixel electrode, and each anode 3 is electrically connected to the drain electrode 245 of the corresponding driving transistor 24 via an electroconductive portion (lead wire) 27. On the other hand, the cathode 7 is a common electrode shared by the light-emitting elements 1R, 1G, and 1B.

The constitution of the light-emitting elements 1G and 1B are the same as that of the light-emitting elements 1R. In FIG. 2, the components illustrated in FIG. 1 are indicated by the same reference numerals as in that drawing. The constitution of the reflection film 32 may be the same or different among the light-emitting elements 1R, 1G, and 1B depending on the wavelength of the light they emit.

The light-emitting elements 1R, 1G, and 1B are separated by partitions 31. On these light-emitting elements 1R, 1G, and 1B, furthermore, an epoxy layer 35 is formed to cover them.

The color filters 19R, 19G, and 19B are formed on this epoxy layer 35 correspondingly to the light-emitting elements 1R, 1G, and 1B.

The color filters 19R convert the white light W emitted by the light-emitting elements 1R into red light. The color filters 19G convert white light W emitted by the light-emitting elements 1G into green light. And the color filters 19B convert white light W emitted by the light-emitting elements 1B into blue light. These color filters 19R, 19G, and 19B are used in combination with the light-emitting elements 1R, 1G, and 1B in this way to display a full-color image.

Furthermore, the color filters 19R, 19G, and 19B are separated by light shields 36. This prevents the light emission from unintended ones of the sub-pixels 100R,100G, and 100B.

On these color filters 19R, 19G, and 19B and the light shields 36, a sealing substrate 20 is formed to cover them.

Although this display panel 100 may be used to display a monochrome image, it can also display a color image when appropriately chosen light-emitting materials are used in its light-emitting elements 1R, 1G, and 1B.

Furthermore, this display panel 100 (an embodiment of the display apparatus according to an aspect of the invention) can be incorporated in various kinds of electronic devices.

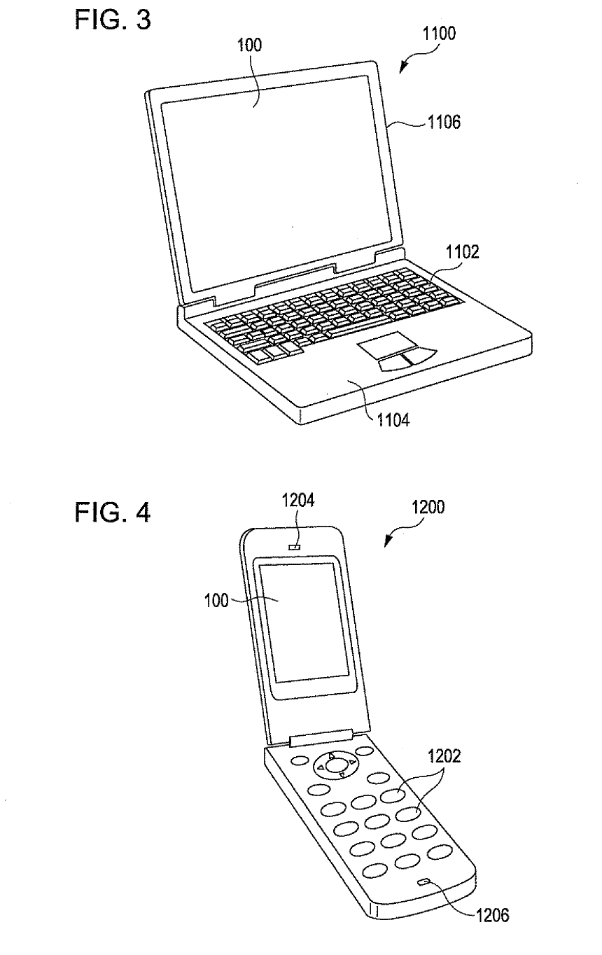

FIG. 3 is a perspective diagram illustrating a constitution of a mobile (or notebook) PC as an application of the electronic device according to an aspect of the invention.

In this drawing, a PC 1100 has a main body 1104 provided with a keyboard 1102 and a display unit 1106 provided with a display portion, and the display unit 1106 is attached to the main body 1104 via a hinge structure to be capable of swinging open and shut.

This PC 1100 uses the display panel 100 as a component of the display portion of the display unit 1106.

FIG. 4 is a perspective diagram illustrating a constitution of a mobile phone (or any other type of personal communicating device) as an application of the electronic device according to an aspect of the invention.

In this drawing, a mobile phone 1200 has a display portion in addition to keys 1202, an earpiece 1204, and a microphone 1206.

This mobile phone 1200 uses the display panel 100 as a component of the display portion.

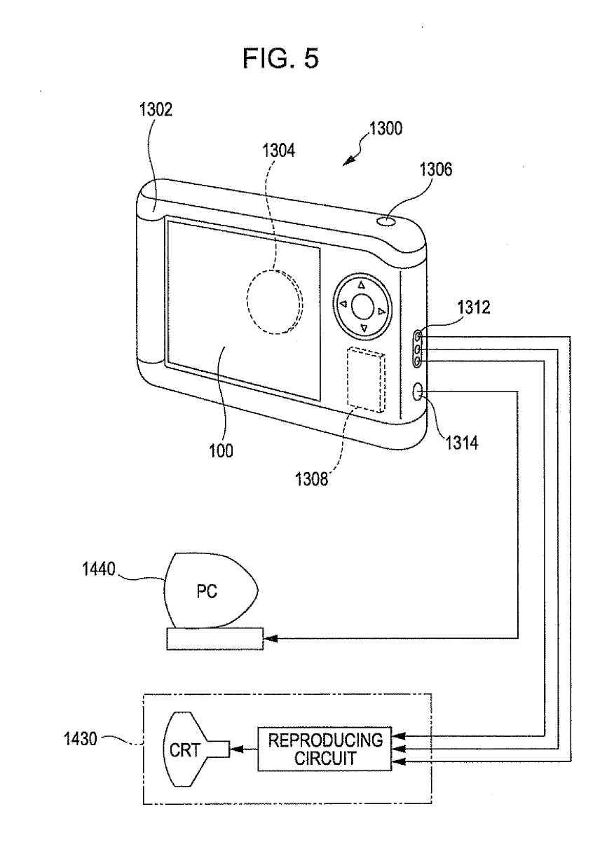

FIG. 5 is a perspective diagram illustrating a constitution of a digital still camera as an application of the electronic device according to an aspect of the invention. This drawing also includes a brief overview of the connection with peripherals.

Note that traditional cameras take pictures by exposing a silver halide photographic film to the optical image of the photographic subject, whereas digital still cameras generate imaging signals (picture signals) by photoelectrically converting the optical image of the photographic subject using a CCD (charge-coupled device) or any other kind of imaging device.

A digital still camera 1300 has a display portion on the back of its case (body) 1302 so that it can display images formed from imaging signals generated by the CCD; this display portion serves as a viewfinder, which displays the photographic subject as an electronic image.

The digital still camera 1300 uses the display panel 100 as a component of this display portion.

The case 1302 contains a circuit board 1308. This circuit board 1308 has a memory in which the imaging signals can be stored (written).

Furthermore, the case 1302 has on its front (the back in the drawing) a light-receiving unit 1304 containing optical lenses (imaging optics), the CCD, and other necessary components.

When the shutter button 1306 is pressed with the image of the photographic subject displayed on this display portion, the imaging signals existing in the CCD at the time are transmitted to and stored in the memory on the circuit board 1308.

This digital still camera 1300 further has a video signal output terminal 1312 and a data input/output terminal 1314 on a lateral side of the case 1302. If necessary, the video signal output 1312 is connected to a television monitor 1430 and the data input/output terminal 1314 is connected to a PC 1440 as illustrated in the drawing. By certain operations, the imaging signals stored in the memory on the circuit board 1308 can be output to the television monitor 1430 or the PC 1440.

Applications of the electronic device according to an aspect of the invention are not limited to those in FIGS. 3, 4, and 5, namely (mobile) PCs, mobile phones, and digital still cameras, and also include the following: televisions, video cameras, video tape recorders with a viewfinder or a direct-view monitor, laptop PCs, automotive navigation systems, pagers, electronic organizers (with or without a communication function), electronic dictionaries, calculators, electronic game consoles, word processors, workstations, videophones, CCTV monitors, electronic binoculars, POS terminals, touch-screen devices (e.g., ATMs and ticket machines), medical devices (e.g., electronic clinical thermometers, manometers, glucose meters, ECG monitors, ultrasonic diagnostic systems, and endoscopic monitors), fishfinders, various kinds of measuring instruments, gauges (e.g., those for automobiles, airplanes, and ships), flight simulators, many other kinds of monitors, and projection display apparatuses such as projectors.

Aspects of the present invention are not limited to the illustrated embodiments of light-emitting elements, light-emitting apparatuses, display apparatuses, and electronic devices.

For instance, the light-emitting element does not necessarily have three light-emitting layers; for example, it may have two light-emitting layers or four or more light-emitting layers, provided that it has at least one light-emitting layer on each side of its carrier-generating layer.

Furthermore, the light-emitting portions (light-emitting units) of the light-emitting element do not necessarily have layers other than the light-emitting layer or layers (such as hole transport and electron transport layers); for example, they may consist of a light-emitting layer or layers only.

### EXAMPLES

The following describes some specific examples of an aspect of the invention.

### Preparation of a Light-Emitting Element

### Example 1

I. First, a transparent glass substrate having an average thickness of 0.5 mm was prepared. Subsequently, an ITO electrode (the anode) having an average thickness of 50 nm was formed over the substrate by sputtering.

The substrate was immersed in acetone and then in 2-propanol, cleaned by sonication, and subjected to oxygen plasma treatment.

II. Then, N,N′-di(1-naphthyl)-N,N′-diphenyl-1,1′-diphenyl-4,4′-diamine(α-NPD) was deposited over the ITO electrode by vacuum deposition to form a hole transport layer (the hole transport layer for the first light-emitting portion) having an average thickness of 50 nm.

III. Then, a first light-emitting layer having an average thickness of 30 nm was formed over the hole transport layer by vacuum deposition.

The first light-emitting layer was made of a mixture of BDAVBi (the guest material) as a blue-light-emitting material and TBADN as the host material. The blue-light-emitting material content (doping level) of the first light-emitting layer was 6.0 wt %.

IV. Then, 1,3-bis(N,N-t-butyl-phenyl)-1,3,4-oxadiazole (OXD-7) as an electron transport material and Li₂O as an electron donor were deposited over the first light-emitting layer by vacuum deposition to form an n-type electron transport layer (the n-type electron transport layer for the carrier-generating layer) having an average thickness of 30 nm. The ratio of the amount of OXD-7 to that of Li₂O in this n-type electron transport layer was 98.5:1.5 on a weight basis.

V. Then, hexacyanohexaazatriphenylene (LG101, LG Chem, Ltd.) as an electron acceptor and Li₂O as an electron donor were deposited over the n-type electron transport layer by vacuum deposition to form an electron-accepting layer having an average thickness of 30 nm. The ratio of the amount of hexacyanohexaazatriphenylene to that of Li₂O in this electron-accepting layer was 98:2 on a weight basis.

By Operations IV and V, a carrier-generating layer having an n-type electron transport layer and an electron-accepting layer was obtained.

VI. Then, N,N′-di(1-naphthyl)-N,N′-diphenyl-1,1′-diphenyl-4,4′-diamine(α-NPD) was deposited over the carrier-generating layer (or more specifically the electron-accepting layer) by vacuum deposition to form a hole transport layer having an average thickness of 20 nm.

VII. Then, a second light-emitting layer having an average thickness of 5 nm was formed over the hole transport layer by vacuum deposition.

The second light-emitting layer was made of a mixture of btp2Ir(acac) (the guest material, chemical formula (1)) as a red-light-emitting material and 4,4′-N,N′-dicarbazole-biphenyl(CBP, chemical formula (3)) as the host material. The red-light-emitting material content (doping level) of the second light-emitting layer was 9.0 wt %.

VIII. Then, a third light-emitting layer having an average thickness of 5 nm was formed over the second light-emitting layer by vacuum deposition.

The third light-emitting layer was made of a mixture of Ir(ppy)₃ (the guest material, chemical formula (2)) as a green-light-emitting material and CBP as the host material. The green-light-emitting material content (doping level) of the third light-emitting layer was 12.0 wt %.

IX. Then, 2,9-dimethyl-4,7-diphenyl-1,10-phenanthroline (BCP), a carbazole derivative, was formed into a film on the third light-emitting layer by vacuum deposition to provide a hole-blocking layer having an average thickness of 10 nm.

X. Then, 1,3-bis(N,N-t-butyl-phenyl)-1,3,4-oxadiazole (OXD-7) was deposited over the hole-blocking layer by vacuum deposition to form an electron transport layer (the electron transport layer for the second light-emitting portion) having an average thickness of 40 nm.

XT. Then, lithium fluoride (LiF) was formed into a film on the electron transport layer by vacuum deposition to provide an electron injection layer having an average thickness of 1.0 nm.

XII. Then, Al was formed into a film on the electron injection layer by vacuum deposition to provide an Al cathode having an average thickness of 100 nm.

XIII. Then, a protection cover made of glass (the sealing member) was put on the obtained light-emitting element to cover the formed layers and fixed and sealed with epoxy resin.

By these operations, a light-emitting element (a tandem light-emitting element) was obtained. This light-emitting element had the following layers stacked on a substrate in the following order: an anode, a hole transport layer, a first light-emitting layer, a carrier-generating layer (an n-type electron transport layer and an electron-accepting layer), another hole transport layer, a second light-emitting layer, a third light-emitting layer, a hole-blocking layer, an electron transport layer, an electron injection layer, and a cathode.

### Example 2

A light-emitting element was prepared by the same operations as in Example 1 except that in Operation V, the ratio of the amount of hexacyanohexaazatriphenylene to that of Li₂O in the electron-accepting layer formed by vacuum deposition was 95:5 on a weight basis.

### Example 3

A light-emitting element was prepared by the same operations as in Example 1 except that in Operation V, the ratio of the amount of hexacyanohexaazatriphenylene to that of Li₂O in the electron-accepting layer formed by vacuum deposition was 90:10 on a weight basis.

### Example 4

A light-emitting element was prepared by the same operations as in Example 1 except that in Operation V, the ratio of the amount of hexacyanohexaazatriphenylene to that of Li₂O in the electron-accepting layer formed by vacuum deposition was 93:7 on a weight basis.

### Example 5

A light-emitting element was prepared by the same operations as in Example 1 except that in Operation V, the ratio of the amount of hexacyanohexaazatriphenylene to that of Li₂O in the electron-accepting layer formed by vacuum deposition was 99.5:0.5 on a weight basis.

### Comparative Example 1

A light-emitting element was prepared by the same operations as in Example 1 except that Operations IV and V, the formation of a carrier-generating layer, were changed as follows.

IV-A. 1,3-Bis(N,N-t-butyl-phenyl)-1,3,4-oxadiazole (OXO-7) was deposited over the first light-emitting layer by vacuum deposition to form an n-type electron transport layer (the n-type electron transport layer for the carrier-generating layer) having an average thickness of 30 nm.

Subsequently, Li₂O was deposited over the n-type electron transport layer by vacuum deposition to form an intermediate layer having an average thickness of 1 nm.

V-A. Then, hexacyanohexaazatriphenylene was deposited over the intermediate layer by vacuum deposition to form an electron-accepting layer having an average thickness of 30 nm.

By Operations IV-A and V-A, a carrier-generating layer having an n-type electron transport layer, an intermediate layer, and an electron-accepting layer was obtained.

### Comparative Example 2

A light-emitting element was prepared by the same operations as in Example I except that Operations IV and V, the formation of a carrier-generating layer, were changed as follows.

IV-B. OXD-7 and Li₂O were deposited over the first light-emitting layer by vacuum deposition to form an n-type electron transport layer (the n-type electron transport layer for the carrier-generating layer) having an average thickness of 30 nm. The ratio of the amount of OXD-7 to that of Li₂O in this n-type electron transport layer was 98.5:1.5 on a weight basis.

V-B. Then, hexacyanohexaazatriphenylene was deposited over the n-type electron transport layer by vacuum deposition to form an electron-accepting layer having an average thickness of 30 nm.

By Operations IV-B and V-B, a carrier-generating layer having an n-type electron transport layer and an electron-accepting layer was obtained.

### Evaluation

A constant electric current of 5 mA/cm² was applied from a direct-current power supply to the light-emitting elements according to the above examples and comparative examples, and the initial driving voltage (A) was measured. Subsequently, the light-emitting elements were stored at a high temperature of 100° C. for 20 hours, and then the driving voltage after high-temperature storage (B) was measured under the above conditions.

The results of these tests are summarized in Table 1. Table 1 also includes the difference between the initial driving voltage (A) and the driving voltage after high-temperature storage (B).

TABLE 1

| | n-Type electron | | Electron-accepting | | | Voltage at a constant current (V) | | |
|---|---|---|---|---|---|---|---|---|
| | transport layer | | layer | | | | After high- | |
| | Electron | Content | Electron | Content | Intermediate | Initial | temp. storage | |
| | donor | (wt %) | donor | (wt %) | layer | (A) | (B) | (B) − (A) |
| Example 1 | Li₂O | 1.5 | Li₂O | 2.0 | — | 5.50 | 5.50 | ±0.00 |
| Example 2 | Li₂O | 1.5 | Li₂O | 5.0 | — | 5.60 | 5.30 | −0.30 |
| Example 3 | Li₂O | 1.5 | Li₂O | 10.0 | — | 6.60 | 7.00 | +0.40 |
| Example 4 | Li₂O | 1.5 | Li₂O | 7.0 | — | 5.50 | 5.51 | +0.01 |
| Example 5 | Li₂O | 1.5 | Li₂O | 0.5 | — | 5.60 | 5.67 | +0.07 |
| Comp. | — | 0 | — | 0 | Li₂O | 5.80 | 8.90 | +3.10 |
| Example 1 | | | | | | | | |
| Comp. | Li₂O | 1.5 | — | 0 | — | 5.60 | 5.70 | +0.10 |
| Example 2 | | | | | | | | |

As is clear from Table 1, the light-emitting elements according to the examples were superior to that according to Comparative Example 1, which had an intermediate layer made of Li₂O, in the driving voltage after high-temperature storage (B) and (B)-(A) because they contained an electron donor both in the n-type electron transport layer and in the electron-accepting layer.

In addition to this, the table shows that the effect of reducing (B)-(A) brought about by the n-type electron transport layer and the electron-accepting layer both containing an electron donor is produced when the Li₂O content of the electron-accepting layer is in a range of 0.5 wt % to 10.0 wt %, inclusive, in particular, 2.0 wt % to 7.0 wt %, inclusive.

This application claims priority from Japanese Patent Application No. 2011-049641 filed in the Japanese patent office on Mar. 7, 2011, the entire disclosure of which is hereby incorporated by reference in its entirely.

What is claimed is:

1. A light-emitting element comprising:
an anode;
a cathode;
a first light-emitting layer that is disposed between the anode and the cathode and, when electric current flows between the anode and the cathode, emits light;
a second light-emitting layer that is disposed between the cathode and the first light-emitting layer and, when electric current flows between the anode and the cathode, emits light; and
a carrier-generating layer that is disposed between the first light-emitting layer and the second light-emitting layer and can generate holes and electrons,
wherein the carrier-generating layer has two layers stacked in contact with each other, an n-type electron transport layer that can transport electrons and is formed to face the first light-emitting layer and an electron-accepting layer that can accept electrons and is formed to face the second light-emitting layer, and
both of the n-type electron transport layer and the electron accepting layer contain an electron injection material.

2. The light-emitting element according to claim 1, wherein the n-type electron transport layer contains an electron transport material in addition to the electron injection material.

3. The light-emitting element according to claim 1, wherein the electron-accepting layer contains an aromatic cyanide in addition to the electron injection material.

4. The light-emitting element according to claim 3, wherein the aromatic cyanide is a hexaazatriphenylene derivative.

5. The light-emitting element according to claim 1, wherein the electron injection material consists of one or more kinds selected from alkali metals, alkaline-earth metals, alkali metal compounds, and alkaline-earth metal compounds.

6. The light-emitting element according to claim 1, wherein the electron injection material contained in the n-type electron transport layer and that contained in the electron-accepting layer are of the same kind.

7. The light-emitting element according to claim 1, wherein an electron injection material content of the electron-accepting layer is in a range of 0.5 wt % (percent by weight) to 10 wt %, inclusive.

8. The light-emitting element according to claim 1, wherein an electron injection material content of the n-type electron transport layer is in a range of 1.0 wt % to 5.0 wt %, inclusive.

9. The light-emitting element according to claim 1, wherein an electron injection material content of the electron-accepting layer is higher than that of the n-type electron transport layer.

10. The light-emitting element according to claim 1, further comprising a third light-emitting layer that is disposed between the second light-emitting layer and the cathode and, when electric current flows between the anode and the cathode, emits light.

11. A light-emitting apparatus comprising the light-emitting element according to claim 1.

12. A light-emitting apparatus comprising the light-emitting element according to claim 2.

13. A light-emitting apparatus comprising the light-emitting element according to claim 3.

14. A light-emitting apparatus comprising the light-emitting element according to claim 4.

15. A light-emitting apparatus comprising the light-emitting element according to claim 5.

16. A light-emitting apparatus comprising the light-emitting element according to claim 6.

17. A light-emitting apparatus comprising the light-emitting element according to claim 7.

18. A light-emitting apparatus comprising the light-emitting element according to claim 8.

19. A display apparatus comprising the light-emitting apparatus according to claim 11.

20. An electronic device comprising the display apparatus according to claim 19.
